(19) United States
(12) Patent Application Publication
(10) Pub. No.: US 2019/0057950 A1
(43) Pub. Date: Feb. 21, 2019

(54) PERMANENT FUNCTIONAL CARRIER SYSTEMS AND METHODS

(71) Applicant: Intel Corporation, Santa Clara, CA (US)

(72) Inventors: Brennen K. Mueller, Hillsboro, OR (US); Patrick Morrow, Portland, OR (US); Paul B. Fischer, Portland, OR (US); Kimin Jun, Hillsboro, OR (US)

(21) Appl. No.: 16/077,568

(22) PCT Filed: Mar. 31, 2016
(86) PCT No.: PCT/US2016/025428

§ 371 Date: Aug. 13, 2018

(51) Int. Cl. H01L 23/00; H01L 23/528; H01L 27/088; H01L 23/522; H01L 21/8234; H01L 23/60; H01L 25/065

(52) U.S. Cl. CPC H01L 24/24; H01L 2225/06524; H01L 27/0886; H01L 23/5223; H01L 23/5228; H01L 21/823431; H01L 24/82; H01L 23/60; H01L 21/823475; H01L 24/19; H01L 25/0657; H01L 2224/24145; H01L 2224/82203; H01L 2224/82897; H01L 2225/06565; H01L 23/528

(57) ABSTRACT

An embodiment includes an apparatus comprising: a first device layer included in a top edge of a semiconductor substrate; metal layers, on the first device layer, including first and second metal layers; a second device layer on the metal layers; and additional metal layers on the second device layer; wherein the second device layer is not included in any semiconductor substrate. Other embodiments are described herein.

### TECHNICAL FIELD

Semiconductor devices including devices that have electrical connections from a backside of the device.

### BACKGROUND

Once semiconductor wafers are prepared, a large number of process steps are still necessary to produce desired semiconductor integrated circuits. In general the steps can be grouped into four areas: front-end processing, back-end processing, test, and packaging.

Front-end processing refers to the initial steps in the fabrication. In this stage the actual semiconductor devices (e.g., transistors) are created. A typical front-end process includes: preparation of the wafer surface, patterning and subsequent implantation of dopants to obtain desired electrical properties, growth or deposition of a gate dielectric, and growth or deposition of insulating materials to isolate neighboring devices.

Once the semiconductor devices have been created they must be interconnected to form the desired electrical circuits. This “back-end processing” involves depositing various layers of metal and insulating material in the desired pattern. Typically the metal layers consist of aluminum, copper, and the like. The insulating material may include SiO₂, low-K materials, and the like. The various metal layers are interconnected by etching holes, called “vias”, in the insulating material and depositing metal (e.g., Tungsten) in them.

Once the back-end processing has been completed, the semiconductor devices are subjected to a variety of electrical tests to determine if they function properly. Finally, the wafer is cut into individual die, which are then packaged in packages (e.g., ceramic or plastic packages) with pins or other connectors to other circuits, power sources, and the like.

### BRIEF DESCRIPTION OF THE DRAWINGS

Features and advantages of embodiments of the present invention will become apparent from the appended claims, the following detailed description of one or more example embodiments, and the corresponding figures. Where considered appropriate, reference labels have been repeated among the figures to indicate corresponding or analogous elements.

FIG. 1 includes a process in an embodiment.

FIGS. 2A-2E include various stages of a system during production of the system in an embodiment.

FIGS. 3A-3B include an embodiment to control electrostatic discharge.

FIGS. 4A, 4B, 4C include an embodiment for passive and/or active devices.

FIGS. 5, 6, and 7 include systems that include embodiments.

### DETAILED DESCRIPTION

Reference will now be made to the drawings wherein like structures may be provided with like suffix reference designations. In order to show the structures of various embodiments more clearly, the drawings included herein are diagrammatic representations of semiconductor/circuit structures. Thus, the actual appearance of the fabricated integrated circuit structures, for example in a photomicrograph, may appear different while still incorporating the claimed structures of the illustrated embodiments. Moreover, the drawings may only show the structures useful to understand the illustrated embodiments. Additional structures known in the art may not have been included to maintain the clarity of the drawings. For example, not every layer of a semiconductor device is necessarily shown. “An embodiment”, “various embodiments” and the like indicate embodiment(s) so described may include particular features, structures, or characteristics, but not every embodiment necessarily includes the particular features, structures, or characteristics. Some embodiments may have some, all, or none of the features described for other embodiments. “First”, “second”, “third” and the like describe a common object and indicate different instances of like objects are being referred to. Such adjectives do not imply objects so described must be in a given sequence, either temporally, spatially, in ranking, or in any other manner. “Connected” may indicate elements are in direct physical or electrical contact with each other and “coupled” may indicate elements co-operate or interact with each other, but they may or may not be in direct physical or electrical contact.

The above passages address a conventional build up that focuses on processing only a single side of the wafer. Specifically, a typical wafer has two main horizontal sides: one side that is processed to include front end transistors and the like, and the opposite side (the “back side” of the wafer) that is not processed. However, in an effort to better utilize the wafer the back side is indeed sometimes processed. Applicant has determined various problems exist for processing the back side of the wafer.

First, in order to perform back-side processing the wafer is commonly flipped so its front-side is bonded to a carrier wafer via oxide fusion bonding. The oxide fusion bonding mechanism typically includes a dielectric at the wafer bonding interface. This dielectric electrically insulates the active components from handlers and electrostatic chucks that couple to the carrier wafer. When an electrostatic potential builds on or between active components, the dielectric at the bonding interface prevents the dissipation of the electric potential to the carrier wafer. An excessive potential can cause electrostatic discharge of the active components, thereby damaging devices in the front-end having a negative effect on device yield.

Second, active and passive circuit elements are commonly found in the transistor plane/front-end. But locating such elements in the back-end (i.e. in the interconnect layers) is of great interest. However, locating those elements in the back-end is difficult due to temperature excursion limits of interconnect materials. In other words, forming high quality transistors and the like may necessitate temperatures of 700 degrees C. or more, whereas metallization layers may be damaged if exposed to temperatures above 450 degrees C. Consequently, these temperature constraints prevent locating active and passive circuit elements in the front-end metal layers.

Fortunately, embodiments disclosed herein address these problems. An embodiment includes a functional carrier wafer that is integrated into the final product. In other words, where a conventional carrier wafer is not included in the final product, an embodiment includes the carrier wafer in the final product. The carrier wafer is “functional” because it includes active and/or passive devices before the carrier wafer is ever bonded to the device (which itself includes passive and active elements). The functional carrier wafer bonds to the device using metallic bonds between metal layers of the device and the functional carrier wafer. These metal-metal bonds electrically connect the active devices to the carrier wafer. This provides protection from electrostatic discharge and allows the integration of separately made circuit components. Put another way, the functional wafer may include a silicon wafer that has a device layer including transistors and the like. Since the devices on the functional carrier wafer can be electrically connected to the bulk silicon, the wafer does not create electrical isolation between the devices logic layer and the electrostatic handling chucks and the like. Instead, the silicon functional carrier allows the charges to disperse and avoid electrostatic discharge.

Such embodiments therefore allow for back-side processing that avoids or lessens the potential for electrostatic damage to the end device. Also, since the functional carrier wafer may have passive/active devices formed in the carrier wafer before metallization layers are formed on the carrier wafer, the system allows for two device layers (each of which may have been processed at over 700 degrees C.) on either side of metal layers (which may not be able to withstand temperatures above 450 degrees C.).

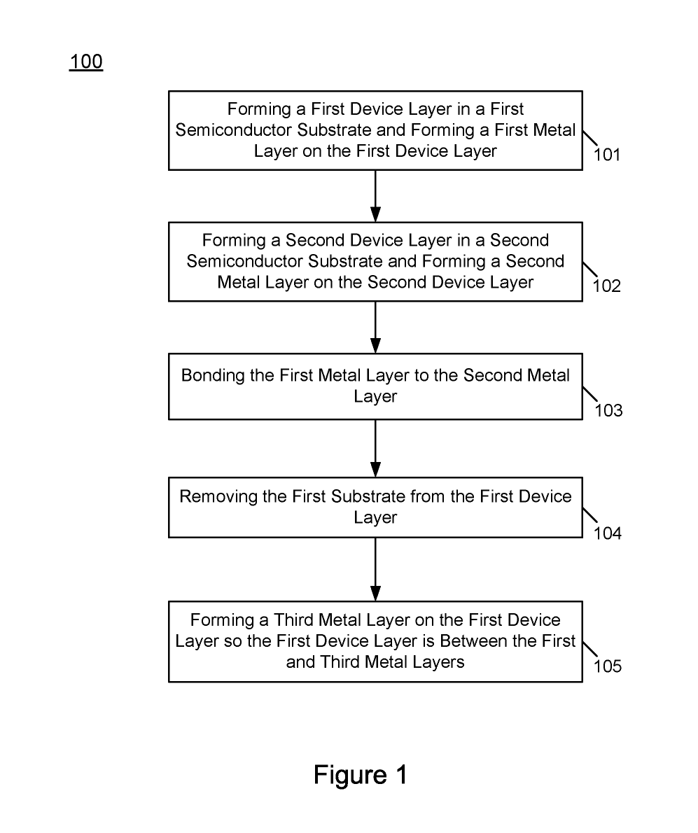

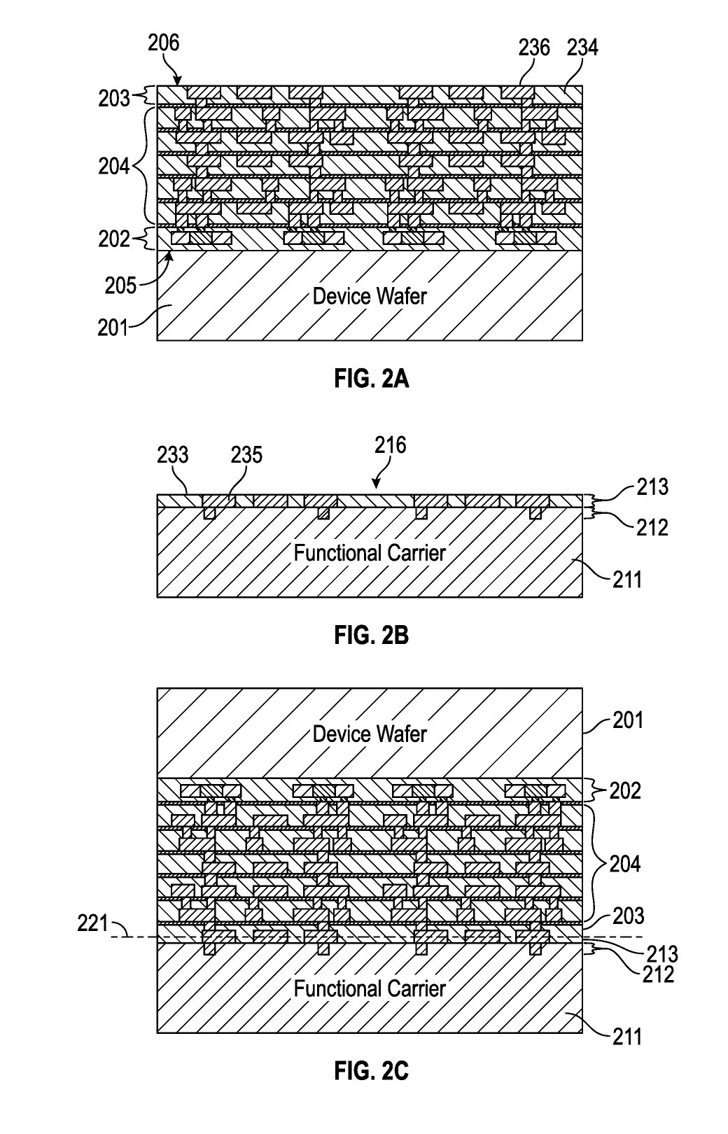

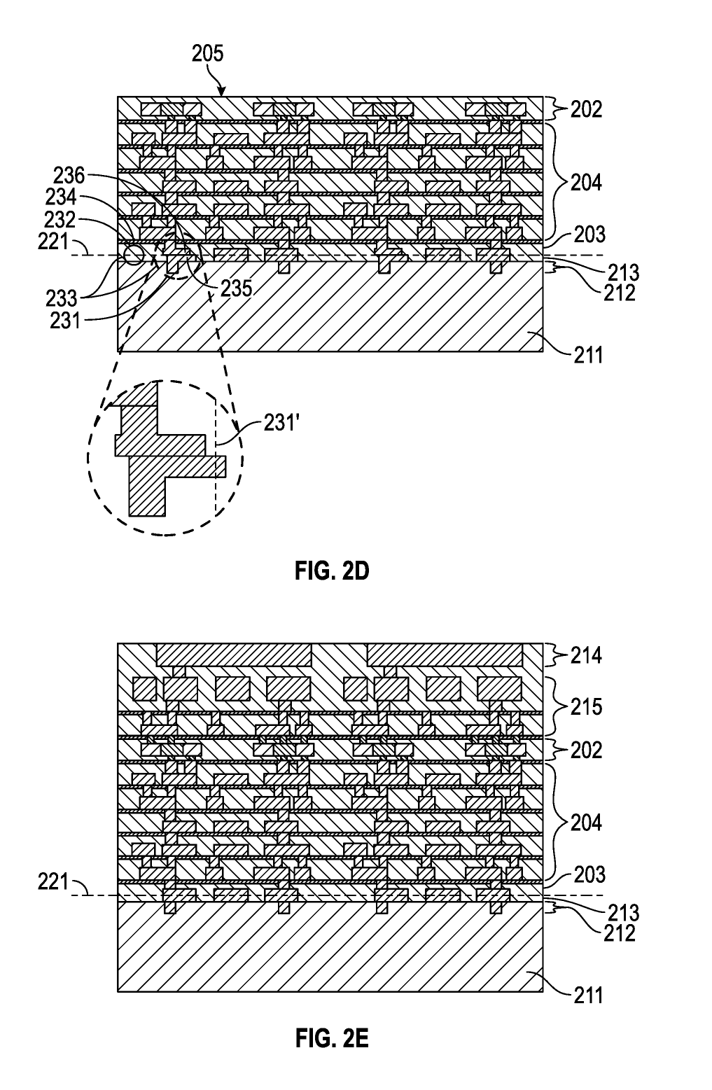

FIG. 1 includes a process 100 in an embodiment. FIGS. 2A-2E include various stages of a system during production of the system in an embodiment. These figures are addressed below.

Process 100 is an improvement over conventional fabrication processes for bonding and grinding wafers. In order to perform a backside reveal process (e.g., grinding away the device wafer), a carrier wafer is conventionally required for mechanical stability of the device layers. However, in process 100 the functionality of the carrier wafer (FIG. 2B) is added before bonding (FIG. 2C), and the bonding method allows for metal-to-metal connections 213.

Block 101 includes forming (FIG. 2A) a first device layer 202 in a first semiconductor substrate 201 and forming a first metal layer 203 on the first device layer. Other metal layers 204 may be included. Block 102 includes forming (FIG. 2B) a second device layer 212 in a second semiconductor substrate 211 and forming a second metal layer 213 on the second device layer.

Thus, two wafers may be fabricated independently. A device wafer (FIG. 2A) may have an active device layer 202 and interconnects 203, 204. The active layer 202 is fabricated so that the backside 205 can be revealed and electrical connections can be made (215 of FIG. 2E). A functional carrier 211 is fabricated with the necessary passive or active electrical components 212. One or more layers of electrical connections 213 are patterned onto the functional components.

Block 103 includes bonding (FIG. 2C) the first metal layer 203 to the second metal layer 213. This bonding occurs along line 221.

Thus, the wafers 201, 211 are bonded face-to-face. The top surfaces 206, 216 of the two wafers are aligned so that the metal layers 203, 213 connect electrically and mechanically after bonding is complete. Many types of wafer bonding could be used for this connection. Two examples are thermocompression bonding and hybrid bonding (which includes oxide/oxide fusion bonding or nitride/nitride fusion bonding).

Block 104 includes removing (FIG. 2D) the first substrate 201 from the first device layer 202. For example, after the wafers are bonded the backside 205 of the active layer 202 is revealed by grinding, etching, and/or polishing.

Block 105 includes forming (FIG. 2E) a third metal layer 214 on the first device layer 202 so the first device layer 202 is between the first metal layer 203 and third metal layer 214. Other metal layers 215 may be added.

Thus, the backside interconnect layers 214, 215 are formed, making connection through the transistor plane 202 and interconnects 204 to functional substrate 211. Multiple layers of metal can be used to scale the metal pitch to a size appropriate for off-chip connections (note how interconnects 214 are larger than those of layers 204). The chips can then be diced and packaged as standard chips.

As seen above, an embodiment provides a solution for electrostatic discharge by using fusion bonding 232 and metal-metal bonding 231 all combined with a backside 205 processing scheme.

Thus, an embodiment provides the bonding of a device wafer 201 to a functional carrier 211 that is incorporated into a final product. The functional carrier 211 may serve many purposes.

First, carrier 211 provides electrostatic discharge structures. For example, conventional systems provide bonding of a device wafer to a carrier wafer through oxide-oxide fusion bonding. This provides a rigid carrier for the devices of the device wafer, but electrically isolates them from the carrier due to the insulation provided by the oxide-oxide bond. Many backside processes require the use of voltage over the process chamber and the use of electrostatic chucks. Electrostatic discharge is a common problem if the devices are not electrically connected to the bulk wafer or to the electrostatic chucks. If silicon is used as a carrier, however, such as the case with wafer 211, doing so allows the metal interconnects 213, 203, 204 to electrically contact the devices 202 and the carrier 211 (which is a semiconductor that can be ground to the chuck and the like) so that ESD does not occur.

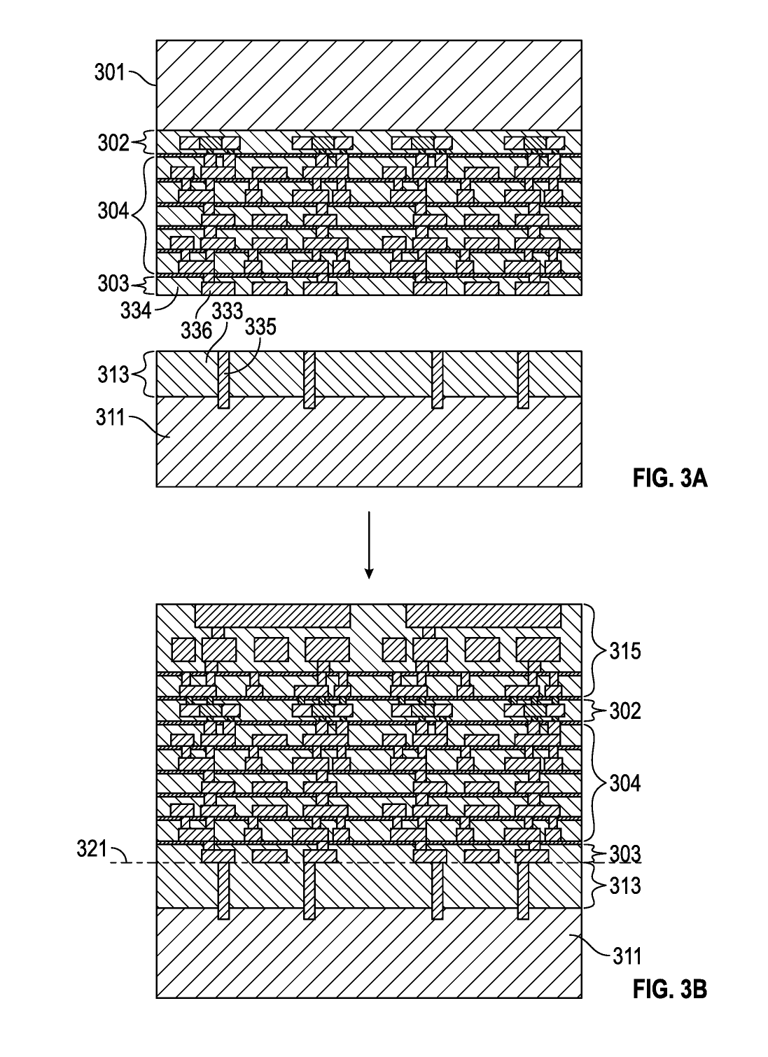

For example, FIG. 3A shows a first wafer 301, with device layer 302 (e.g., including transistors), metal layers 304, and top metal layer 303. Metal layer 313 is on functional carrier wafer 311. Metal layer 313 includes dielectric portion 333 and metal portion 335. FIG. 3B shows metal portions 335, 336 bonded to each other and dielectric portions 334, 333 bonded together. As a result, semiconductor wafer 311 (which couples to transport chucks) electrically couples the chucks and related processing equipment to device layer 302 by way of layers 304, 303, 313, thereby lowering the chances of damage to devices in layer 302 due to electrostatic discharge. As an aside, buildup metal layers 315 are also shown.

Second, embodiments provide for back-end capacitors. For example, a metal-insulator-metal capacitor (MIMCap) may be included within conventional metal layers. However, doing so in embodiments such as the embodiment of FIG. 2E allows for the fabrication of these capacitors separate from the rest of the device wafer. The removal of the interconnect temperature restriction could allow for better materials or for higher quality deposition of the materials, improving the electrical properties. The need for electrical connections in only one direction can also allow for high area of the capacitor and increased capacitance.

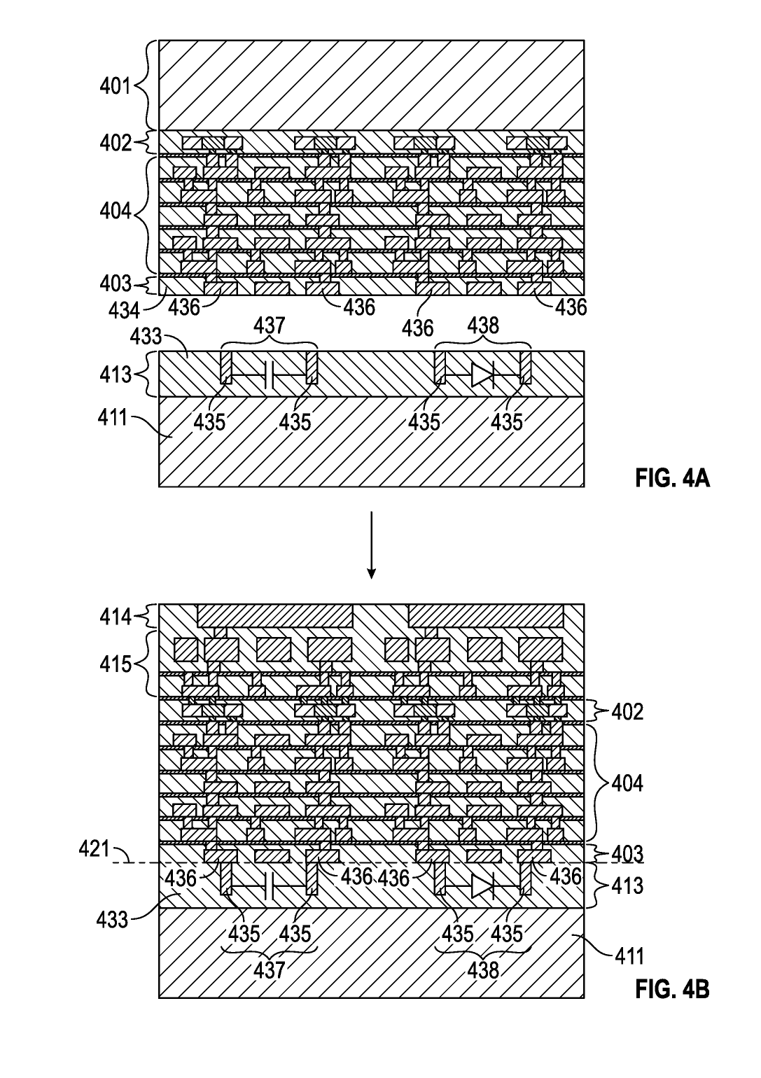

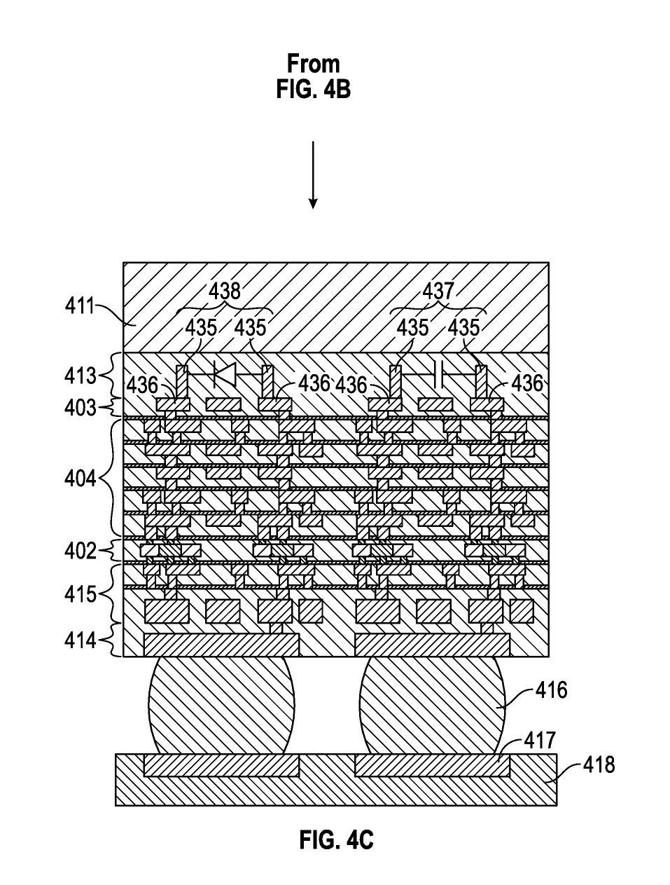

FIGS. 4A, 4B, 4C show how MIMCaps and other devices, such as diodes, can be formed before wafer 411 couples to device layer 402. For example, FIG. 4A shows a first wafer 401, with device layer 402 (e.g., including transistors), metal layers 404, and top metal layer 403. Metal layer 413 is on functional carrier wafer 411. Metal layer 413 includes dielectric portion 433 and metal portions 435. Metal portions 435 will form capacitor 437 and diode 438 (where capacitor 437 and diose 438 are illustrated in greatly simplified form). FIG. 4B shows metal portions 435, 436 bonded to each other and dielectric portions 434, 433 bonded together. As a result, capacitors and/or diodes 437, 438 may have been fabricated (at temperatures above 450 degrees C.) before being coupled to interconnect layers that need to 404 that need to be processed below 405 degrees C. Eventually C4 bumps 416 may relay power to capacitors and/or diodes 437, 438 by way of landing pad 417 and a power distribution substrate 418.

Third, embodiments provide for back-end resistors. Conventional back-end resistors are restricted to the same temperatures and materials in the interconnects 204. However, fabricating the resistors on the carrier 212 enables resistors made from silicon or many other materials. Not only can these have much higher resistance than copper lines (e.g., layers 204), but they can be tunable to fit the needs of a circuit.

Fourth, embodiments provide for back-end active devices. For example, transistors, diodes, and other active and/or passive circuit elements can be built on the functional carrier at layer 212. Beside the temperatures possible when forming layer 212 (e.g., above 700 degrees C.), one benefit is that these device layers 202, 212 would not have to be built under the same design rules. For example, they could have differing critical dimensions (CD) (where CD relates to dimensions of the smallest geometrical features (e.g., width of interconnect line, contacts, trenches, etc.) which can be formed during semiconductor device/circuit manufacturing). It is historically difficult to fabricate large and small dimension devices at the same time because many fabrication processes rely on the uniformity of device sizes. Placing these elements in the interconnect layers (e.g., layer 202 between layers 204, 215) could also enable unique circuit designs, potentially shortening interconnect length (and RC delay) between active components.

Backside processing such as the processing embodiments addressed herein may allow for power delivery (e.g., coupling bumps to layer 214) from the backside of the wafer. Electrostatic discharge protection is provided for this processing. Using a functional carrier also allows the formation of more complex circuit elements that may benefit power and performance.

Various embodiments include a semiconductive substrate. Such a substrate may be a bulk semiconductive material this is part of a wafer. In an embodiment, the semiconductive substrate is a bulk semiconductive material as part of a chip that has been singulated from a wafer. In an embodiment, the semiconductive substrate is a semiconductive material that is formed above an insulator such as a semiconductor on insulator (SOI) substrate. In an embodiment, the semiconductive substrate is a prominent structure such as a fin that extends above a bulk semiconductive material.

The following examples pertain to further embodiments.

Example 1 includes an apparatus comprising: a first device layer included in a top edge of a semiconductor substrate; metal layers, on the first device layer, including first and second metal layers; a second device layer on the metal layers; and additional metal layers on the second device layer.

Another version of Example 1 includes an apparatus comprising: a first device layer included in a top edge of a semiconductor substrate; metal layers, on the first device layer, including first and second metal layers; a second device layer on the metal layers; and additional metal layers on the second device layer; wherein the second device layer is not included in any semiconductor substrate.

For example, the first device layer may include layer 212 and the first and second metal layers may include layers 213, 203. The second device layer may include layer 202.

In example 2 the subject matter of the Example 1 can optionally include the first metal layer includes a first dielectric portion coplanar with a first metal portion; the second metal layer includes a second dielectric portion coplanar with a second metal portion; and the first metal portion is bonded to the second metal portion.

For example, “a first dielectric portion coplanar with a first metal portion” includes a situation where the metal and dielectric are coplanar at the bonding interface.

The first dielectric portion 233 may be coplanar with metal portion 235. Also, dielectric portion 234 may be coplanar with metal portion 236. Metal portions 235, 236 bond to each other.

In example 3 the subject matter of the Examples 1-2 can optionally include wherein the first metal portion is horizontally offset from the second metal portion such that a vertical axis, orthogonal to the substrate, intersects one of the first and second metal portions but not another of the first and second metal portions.

For example, axis 231′ shows such an offset that is may occur due to less than perfect alignment between metal portions 235, 236 along bond line 221.

In example 4 the subject matter of the Examples 1-3 can optionally include wherein the first dielectric portion is bonded to the second dielectric portion.

In example 5 the subject matter of the Examples 1-4 can optionally include wherein the first dielectric portion is bonded to the second dielectric portion with at least one of an oxide-oxide fusion bond and a nitride-nitride fusion bond.

Through fusion bonding, covalent bonds are formed (typically Si—O—Si) between bonding interfaces. Fusion bonding often requires no compression to achieve the fusing of the two interfaces.

In example 6 the subject matter of the Examples 1-5 can optionally include wherein the first metal portion is bonded to the second metal portion with a thermocompression bond.

For thermocompression bonding, heat and compressive force are applied to the bonding wafers. This causes diffusion of the metal and effectively welds the two metal structures together.

In example 7 the subject matter of the Examples 1-6 can optionally include wherein the first and second device layers each include switching devices.

Switching devices may include planar or poly-gate transistors, diodes, and the like.

In example 8 the subject matter of the Examples 1-7 can optionally include wherein the first device layer has a first critical dimension (CD) and the second device layer includes a second CD unequal to the first CD.

In example 9 the subject matter of the Examples 1-8 can optionally include wherein the first device layer includes a first switching device having a first fin with a first maximum width and the second device layer includes a second switching device having a second fin with a second maximum width unequal to the first maximum width.

In such an example, the fin may have a major horizontal axis and a minor horizontal axis that defines the fin width.

In example 10 the subject matter of the Examples 1-9 can optionally include wherein at least one of the metal layers and the additional metal layers include a metal-insulator-metal (MIM) capacitor.

In example 11 the subject matter of the Examples 1-10 can optionally include wherein at least one of the first and second device layers includes a resistor.

Example 12 includes an apparatus comprising: a first device layer included in a top edge of a semiconductor substrate; metal layers, on the first device layer, including first and second metal layers; and a second device layer on the metal layers; wherein (a) the first metal layer a includes a first dielectric portion coplanar with a first metal portion; (b) the second metal layer includes a second dielectric portion coplanar with a second metal portion; and (c) the first metal portion is bonded to the second metal portion.

Another version of Example 12 includes an apparatus comprising: a first device layer included in a top edge of a semiconductor substrate; metal layers, on the first device layer, including first and second metal layers; and a second device layer on the metal layers; wherein (a) the second device layer is not included in any semiconductor substrate; (b) the first metal layer a includes a first dielectric portion coplanar with a first metal portion; (c) the second metal layer includes a second dielectric portion coplanar with a second metal portion; and (d) the first metal portion is bonded to the second metal portion.

Another version of Example 12 includes an apparatus comprising: a first device layer included in a top edge of a semiconductor substrate; metal layers, on the first device layer, including first and second metal layers; and a second device layer on the metal layers; wherein (a) the second device layer has been separated from another semiconductor substrate; (b) the first metal layer a includes a first dielectric portion coplanar with a first metal portion; (c) the second metal layer includes a second dielectric portion coplanar with a second metal portion; and (d) the first metal portion is bonded to the second metal portion.

For instance, imaging may reveal “the second device layer has been separated from another semiconductor substrate” by revealing evidence that the “another” substrate was grinded or polished away from the second device layer.

Example 12 includes an apparatus comprising: a first device layer included in a top edge of a semiconductor substrate; metal layers, on the first device layer, including first and second metal layers; and a second device layer on the metal layers; wherein (a) the second device layer is not included in any semiconductor substrate; (b) the first metal layer includes a first dielectric portion coplanar with a first metal portion; (c) the second metal layer includes a second dielectric portion coplanar with a second metal portion; and (d) the first metal portion is bonded to the second metal portion.

In example 13 the subject matter of the Example 12 can optionally include wherein the first dielectric portion is bonded to the second dielectric portion with at least one of an oxide-oxide fusion bond and a nitride-nitride fusion bond.

In example 14 the subject matter of the Examples 12-13 can optionally include wherein the first and second device layers each include switching devices.

Example 15 includes a method comprising: forming a first device layer in a first semiconductor substrate; forming a first metal layer on the first device layer; forming a second device layer in a second semiconductor substrate; forming a second metal layer on the second device layer; and bonding the first metal layer to the second metal layer.

In example 16 the subject matter of the Example 15 can optionally include removing the first substrate from the first device layer.

In example 17 the subject matter of the Examples 15-16 can optionally include forming a third metal layer on the first device layer so the first device layer is between the first and third metal layers.

In example 18 the subject matter of the Examples 15-17 can optionally include wherein the first metal layer includes a first metal portion horizontally offset from a second metal portion of the second metal layer such that a vertical axis, orthogonal to the substrate, intersects one of the first and second metal portions but not another of the first and second metal portions.

In example 19 the subject matter of the Examples 15-18 can optionally include wherein a first dielectric portion of the first metal layer is bonded to a second dielectric portion of the second metal layer with a fusion bond.

In example 20 the subject matter of the Examples 15-19 can optionally include wherein the first metal layer is bonded to the second metal layer with a thermocompression bond.

Example 21 includes an apparatus comprising: a semiconductor substrate; metal layers, on the first device layer, including first and second metal layers; and a second device layer on the metal layers; wherein (a) the first metal layer a includes a first dielectric portion coplanar with a first metal portion; (b) the second metal layer includes a second dielectric portion coplanar with a second metal portion; and (c) the first metal portion is bonded to the second metal portion.

In example 22 the subject matter of Example 21 can optionally include wherein the first dielectric portion is bonded to the second dielectric portion with at least one of an oxide-oxide fusion bond and a nitride-nitride fusion bond.

In example 23 the subject matter of the Examples 21-22 can optionally include wherein the first metal layer includes at least one of a diode and a capacitor.

For example, see FIG. 4C.

In example 24 the subject matter of the Examples 21-23 can optionally include wherein the first metal layer includes an electrostatic discharge metal path electrically coupling the substrate to the second metal layer and the second device layer.

For example, see FIG. 3B.

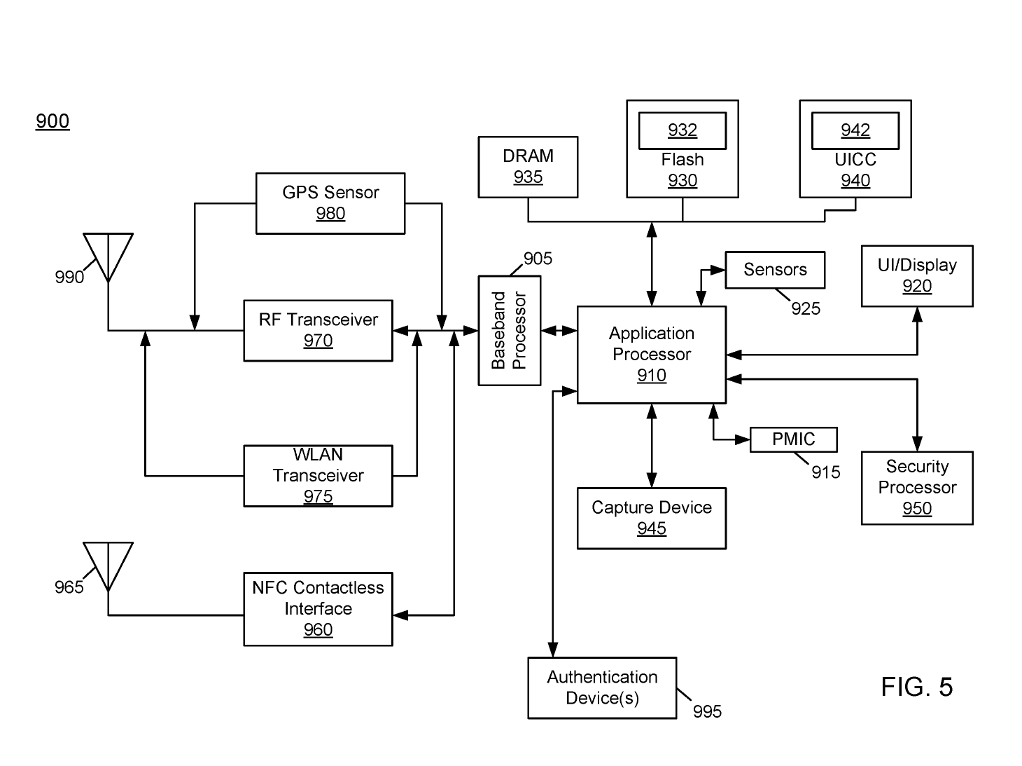

FIGS. 5, 6, 7 each include a system that may include any of the above described embodiments. FIGS. 5, 6, and 7 include block diagrams of systems 900, 1000, 1300 in accordance with embodiments. Each of those systems may include hundreds or thousands of the above described back-side processed devices (FIG. 2E) and be critical to functions (e.g., memory functions of memories that include such back-side processed devices) in those systems. The back-side processed devices may be included in, for example, elements 910, 930, 1070, 1032, 1090, 1310, 1340, 1380, and the like. Systems 900, 1000, 1300 may be included in, for example, a mobile computing node such as a cellular phone, smartphone, tablet, Ultrabook®, notebook, laptop, personal digital assistant, and mobile processor based platform. The size savings and power efficiency of such devices accumulates when the back-side processed devices are deployed in mass and provides significant performance advantages to such computing nodes.

Referring now to FIG. 5, shown is a block diagram of an example system with which embodiments can be used. As seen, system 900 may be a smartphone or other wireless communicator or any other IoT device. A baseband processor 905 is configured to perform various signal processing with regard to communication signals to be transmitted from or received by the system. In turn, baseband processor 905 is coupled to an application processor 910, which may be a main CPU of the system to execute an OS and other system software, in addition to user applications such as many well-known social media and multimedia apps. Application processor 910 may further be configured to perform a variety of other computing operations for the device.

In turn, application processor 910 can couple to a user interface/display 920, e.g., a touch screen display. In addition, application processor 910 may couple to a memory system including a non-volatile memory, namely a flash memory 930 and a system memory, namely a DRAM 935. In some embodiments, flash memory 930 may include a secure portion 932 in which secrets and other sensitive information may be stored. As further seen, application processor 910 also couples to a capture device 945 such as one or more image capture devices that can record video and/or still images.

A universal integrated circuit card (UICC) 940 comprises a subscriber identity module, which in some embodiments includes a secure storage 942 to store secure user information. System 900 may further include a security processor 950 that may couple to application processor 910. A plurality of sensors 925, including one or more multi-axis accelerometers may couple to application processor 910 to enable input of a variety of sensed information such as motion and other environmental information. In addition, one or more authentication devices 995 may be used to receive, e.g., user biometric input for use in authentication operations.

As further illustrated, a near field communication (NFC) contactless interface 960 is provided that communicates in a NFC near field via an NFC antenna 965. While separate antennae are shown, understand that in some implementations one antenna or a different set of antennae may be provided to enable various wireless functionalities.

A power management integrated circuit (PMIC) 915 couples to application processor 910 to perform platform level power management. To this end, PMIC 915 may issue power management requests to application processor 910 to enter certain low power states as desired. Furthermore, based on platform constraints, PMIC 915 may also control the power level of other components of system 900.

To enable communications to be transmitted and received such as in one or more IoT networks, various circuitries may be coupled between baseband processor 905 and an antenna 990. Specifically, a radio frequency (RF) transceiver 970 and a wireless local area network (WLAN) transceiver 975 may be present. In general, RF transceiver 970 may be used to receive and transmit wireless data and calls according to a given wireless communication protocol such as 3G or 4G wireless communication protocol such as in accordance with a code division multiple access (CDMA), global system for mobile communication (GSM), long term evolution (LTE) or other protocol. In addition a GPS sensor 980 may be present, with location information being provided to security processor 950 for use as described herein when context information is to be used in a pairing process. Other wireless communications such as receipt or transmission of radio signals, e.g., AM/FM and other signals may also be provided. In addition, via WLAN transceiver 975, local wireless communications, such as according to a Bluetooth™ or IEEE 802.11 standard can also be realized.

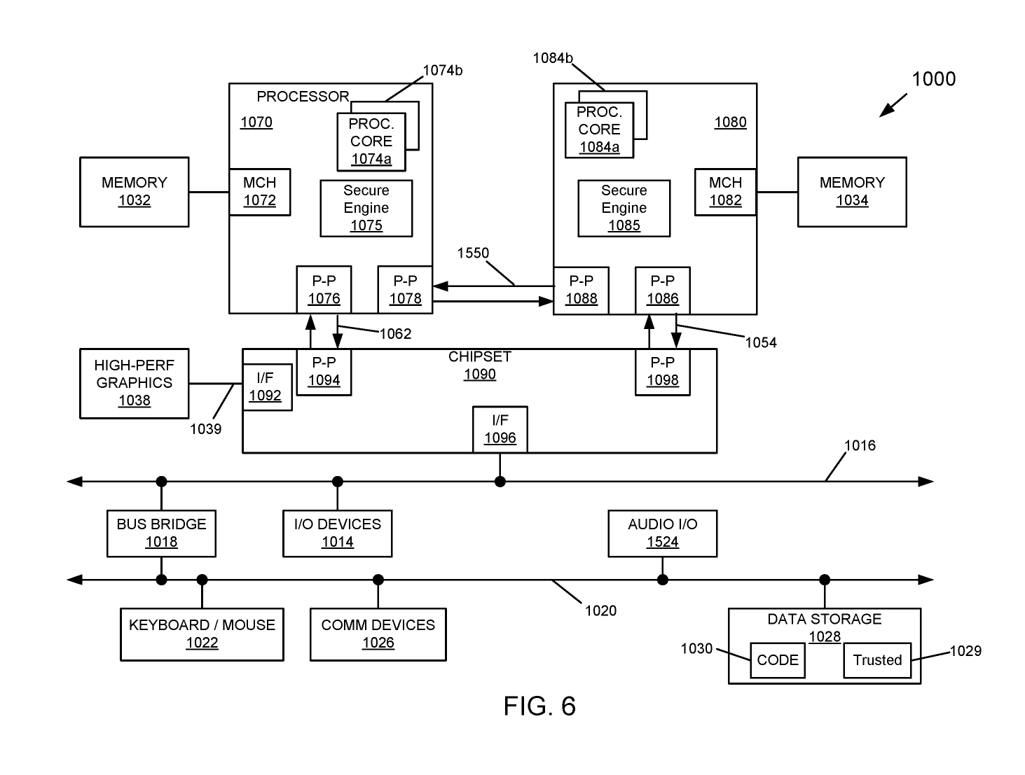

Referring now to FIG. 6, shown is a block diagram of a system in accordance with another embodiment of the present invention. Multiprocessor system 1000 is a point-to-point interconnect system such as a server system, and includes a first processor 1070 and a second processor 1080 coupled via a point-to-point interconnect 1050. Each of processors 1070 and 1080 may be multicore processors such as SoCs, including first and second processor cores (i.e., processor cores 1074a and 1074b and processor cores 1084a and 1084b), although potentially many more cores may be present in the processors. In addition, processors 1070 and 1080 each may include a secure engine 1075 and 1085 to perform security operations such as key management, attestations, IoT network onboarding or so forth.

First processor 1070 further includes a memory controller hub (MCH) 1072 and point-to-point (P-P) interfaces 1076 and 1078. Similarly, second processor 1080 includes a MCH 1082 and P-P interfaces 1086 and 1088. MCH's 1072 and 1082 couple the processors to respective memories, namely a memory 1032 and a memory 1034, which may be portions of main memory (e.g., a DRAM) locally attached to the respective processors. First processor 1070 and second processor 1080 may be coupled to a chipset 1090 via P-P interconnects 1052 and 1054, respectively. As shown in FIG. 6, chipset 1090 includes P-P interfaces 1094 and 1098.

Furthermore, chipset 1090 includes an interface 1092 to couple chipset 1090 with a high performance graphics engine 1038, by a P-P interconnect 1039. In turn, chipset 1090 may be coupled to a first bus 1016 via an interface 1096. Various input/output (I/O) devices 1014 may be coupled to first bus 1016, along with a bus bridge 1018 which couples first bus 1016 to a second bus 1020. Various devices may be coupled to second bus 1020 including, for example, a keyboard/mouse 1022, communication devices 1026 and a data storage unit 1028 such as a non-volatile storage or other mass storage device. As seen, data storage unit 1028 may include code 1030, in one embodiment. As further seen, data storage unit 1028 also includes a trusted storage 1029 to store sensitive information to be protected. Further, an audio I/O 1024 may be coupled to second bus 1020.

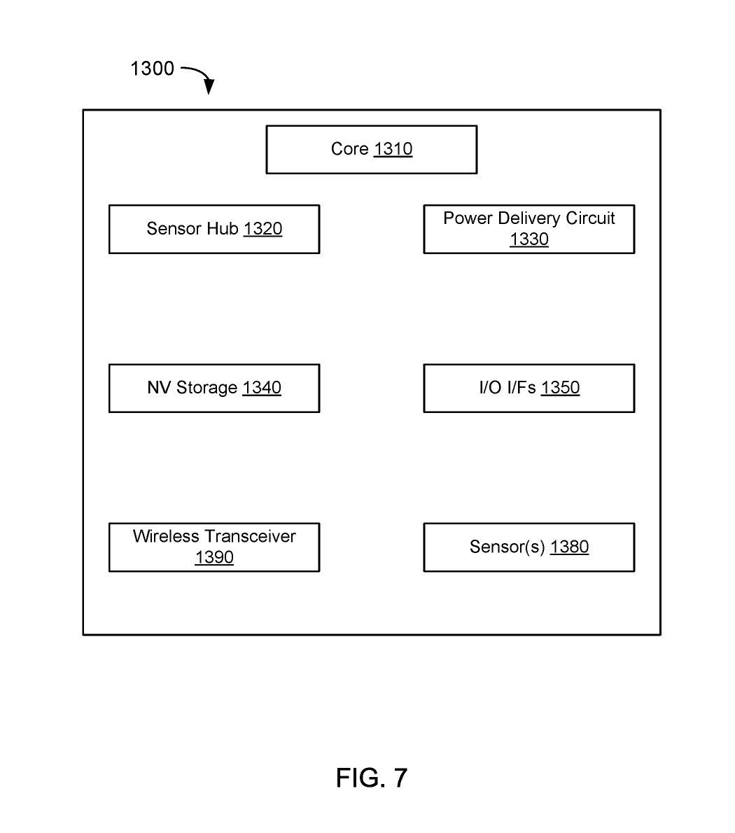

Embodiments may be used in environments where Internet of Things (IoT) devices may include wearable devices or other small form factor IoT devices. Referring now to FIG. 7, shown is a block diagram of a wearable module 1300 in accordance with another embodiment. In one particular implementation, module 1300 may be an Intel® Curie™ module that includes multiple components adapted within a single small module that can be implemented as all or part of a wearable device. As seen, module 1300 includes a core 1310 (of course in other embodiments more than one core may be present). Such core may be a relatively low complexity in-order core, such as based on an Intel Architecture® Quark™ design. In some embodiments, core 1310 may implement a TEE as described herein. Core 1310 couples to various components including a sensor hub 1320, which may be configured to interact with a plurality of sensors 1380, such as one or more biometric, motion environmental or other sensors. A power delivery circuit 1330 is present, along with a non-volatile storage 1340. In an embodiment, this circuit may include a rechargeable battery and a recharging circuit, which may in one embodiment receive charging power wirelessly. One or more input/output (IO) interfaces 1350, such as one or more interfaces compatible with one or more of USB/SPI/I2C/GPIO protocols, may be present. In addition, a wireless transceiver 1390, which may be a Bluetooth™ low energy or other short-range wireless transceiver is present to enable wireless communications as described herein. Understand that in different implementations a wearable module can take many other forms. Wearable and/or IoT devices have, in comparison with a typical general purpose CPU or a GPU, a small form factor, low power requirements, limited instruction sets, relatively slow computation throughput, or any of the above.

Various embodiments include a semiconductive substrate. Such a substrate may be a bulk semiconductive material this is part of a wafer. In an embodiment, the semiconductive substrate is a bulk semiconductive material as part of a chip that has been singulated from a wafer. In an embodiment, the semiconductive substrate is a semiconductive material that is formed above an insulator such as a semiconductor on insulator (SOI) substrate. In an embodiment, the semiconductive substrate is a prominent structure such as a fin that extends above a bulk semiconductive material.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. An apparatus comprising:
a first device layer included in a top edge of a semiconductor substrate;
metal layers, on the first device layer, including first and second metal layers;
a second device layer on the metal layers; and
additional metal layers on the second device layer.

2. The apparatus of claim 1, wherein:
the first metal layer includes a first dielectric portion coplanar with a first metal portion;
the second metal layer includes a second dielectric portion coplanar with a second metal portion; and
the first metal portion is bonded to the second metal portion.

3. The apparatus of claim 3, wherein the first metal portion is horizontally offset from the second metal portion such that a vertical axis, orthogonal to the substrate, intersects one of the first and second metal portions but not another of the first and second metal portions.

4. The apparatus of claim 3, wherein the first dielectric portion is bonded to the second dielectric portion.

5. The apparatus of claim 3, wherein the first dielectric portion is bonded to the second dielectric portion with at least one of an oxide-oxide fusion bond and a nitride-nitride fusion bond.

6. The apparatus of claim 3, wherein the first metal portion is bonded to the second metal portion with a thermocompression bond.

7. The apparatus of claim 1, wherein the first and second device layers each include switching devices.

8. The apparatus of claim 1, wherein the first device layer has a first critical dimension (CD) and the second device layer includes a second CD unequal to the first CD.

9. The apparatus of claim 1, wherein the first device layer includes a first switching device having a first fin with a first maximum width and the second device layer includes a second switching device having a second fin with a second maximum width unequal to the first maximum width.

10. The apparatus of claim 1, wherein at least one of the metal layers and the additional metal layers include a metal-insulator-metal (MIM) capacitor.

11. The apparatus of claim 1, wherein at least one of the first and second device layers includes a resistor.

12. An apparatus comprising:
a first device layer included in a top edge of a semiconductor substrate;
metal layers, on the first device layer, including first and second metal layers; and
a second device layer on the metal layers;
wherein (a) the first metal layer a includes a first dielectric portion coplanar with a first metal portion; (b) the second metal layer includes a second dielectric portion coplanar with a second metal portion; and (c) the first metal portion is bonded to the second metal portion.

13. The apparatus of claim 12, wherein the first dielectric portion is bonded to the second dielectric portion with at least one of an oxide-oxide fusion bond and a nitride-nitride fusion bond.

14. The apparatus of claim 12, wherein the first and second device layers each include switching devices.

15. A method comprising:
forming a first device layer in a first semiconductor substrate;
forming a first metal layer on the first device layer;
forming a second device layer in a second semiconductor substrate;
forming a second metal layer on the second device layer; and
bonding the first metal layer to the second metal layer.

16. The method of claim 15 comprising removing the first substrate from the first device layer.

17. The method of claim 16 comprising forming a third metal layer on the first device layer so the first device layer is between the first and third metal layers.

18. The method of claim 16, wherein the first metal layer includes a first metal portion horizontally offset from a second metal portion of the second metal layer such that a vertical axis, orthogonal to the substrate, intersects one of the first and second metal portions but not another of the first and second metal portions.

19. The method of claim 18, wherein a first dielectric portion of the first metal layer is bonded to a second dielectric portion of the second metal layer with a fusion bond.

20. The method of claim 18, wherein the first metal layer is bonded to the second metal layer with a thermocompression bond.

21. An apparatus comprising:
a semiconductor substrate;
metal layers, on the first device layer, including first and second metal layers; and
a second device layer on the metal layers;
wherein (a) the first metal layer a includes a first dielectric portion coplanar with a first metal portion; (b) the second metal layer includes a second dielectric portion coplanar with a second metal portion; and (c) the first metal portion is bonded to the second metal portion.

22. The apparatus of claim 21, wherein the first dielectric portion is bonded to the second dielectric portion with at least one of an oxide-oxide fusion bond and a nitride-nitride fusion bond.

23. The apparatus of claim 22, wherein the first metal layer includes at least one of a diode and a capacitor.

24. The apparatus of claim 22, wherein the first metal layer includes an electrostatic discharge metal path electrically coupling the substrate to the second metal layer and the second device layer.
